(19) United States
(12) Patent Application Publication
(10) Pub. No.: US 2006/0170437 A1
(43) Pub. Date: Aug. 3, 2006

(54) Probe card for testing a plurality of semiconductor chips and method thereof

(76) Inventors: Sang-Kyu Yoo, Yongin-si (KR); Ki-Sang Kang, Yongin-si (KR); Hoon-Jung Kim, Yongin-si (KR); Sung-Mo Kang, Suwon-si (KR); Chang-Hyun Cho, Suwon-si (KR)

Correspondence Address: HARNESS, DICKEY & PIERCE, P.L.C., P.O. BOX 8910, RESTON, VA, 20195, US

(21) Appl. No.: 11/330,399

(22) Filed: Jan. 12, 2006

(30) Foreign Application Priority Data
Jan. 12, 2005 (KR) 10-2005-0002873

(51) Int. Cl. G01R 31/02

(52) U.S. Cl. 324/754

(57) ABSTRACT

A probe card for that may be used to test a plurality of semiconductor chips formed on a wafer. The probe card may include a substrate; a plurality of probe blocks that form a pattern corresponding to the pattern formed by the plurality of semiconductor chips formed on the wafer; and a plurality of probe needles formed in the probe blocks and arranged in a pattern corresponding to a plurality of pads formed in the plurality of semiconductor chips. The use of the probe card may decrease the testing time for the wafer.

### PRIORITY STATEMENT

This application claims priority under 35 U.S.C. § 119 to Korean Patent Application No. 10-2005-0002873, filed on Jan. 12, 2005, in the Korean Intellectual Property Office (KIPO), the disclosure of which is incorporated herein in its entirety by reference.

### BACKGROUND OF THE INVENTION

1. Field of the Invention

Example embodiments of present invention relate to a probe card for testing a plurality of semiconductor chips formed on a wafer, and more particularly, to a probe card for testing a plurality of semiconductor chips at the same time, thus decreasing testing time, and method thereof.

2. Description of the Related Art

When the manufacturing of semiconductor chips on a wafer is completed, an electric die sort (EDS) test, which is performed to test electrical characteristics of the semiconductor chips, may be performed before packaging. In order to perform the EDS test, probe cards which transfer electric signals from testing equipment to semiconductor chips may be required. Recently, techniques using a probe card for testing a plurality of semiconductor chips which can test all of the chips or some of the chips at once have been developed.

FIG. 1 is a plan view of a conventional probe card 101 that may be used to test a plurality of semiconductor chips. Referring to FIG. 1, the probe card 101 may include a circuit substrate 111, a fixing plate 121, a plurality of probe blocks 141, and a plurality of probe needles 151.

The circuit substrate 111 may have a plurality of contact pads 113 and a probe area 131, and may be fixed by the fixing plate 121.

The probe blocks 141 may be adjacent to each other in the probe area 131.

The probe needles 151 may be installed in the probe blocks 141. The probe needles 151 may correspond to pads (not shown) of the semiconductor chips 221 illustrated in FIG. 2 formed on a wafer 211 illustrated in FIG. 2.

As illustrated in FIG. 1, the shape formed by the probe blocks 141 may be quadrilateral.

FIG. 2 is a plan view of the wafer 211 with the semiconductor chips 221 thereon. Referring to FIG. 2, the semiconductor chips 221 may be formed on the wafer 211. The sizes of the semiconductor chips 221 may determine the number of semiconductor chips 221 that may be formed on the wafer 211.

For example, when the wafer 211 is included in a flash memory chip and has a diameter of 8-inches and the semiconductor chips 221 are each X(9,100 μm)×Y(16,040 μm), 175 semiconductor chips 221 may be formed on the 8-inch wafer 211.

When the probe area 131 of the probe card 101 has a size of X(9,100 μm)×Y(16,040 μm) and the EDS test is performed on the 175 semiconductor chips 221 on the 8-inch wafer 211, 128 probe blocks 141 may be formed on the probe card 101. The number of the probe blocks 141 may be given by
Z=X×Y=16×8=128 (in number) Equation (1)
wherein X is the maximum number of probe blocks arranged along the x-axis of the probe area 131, Y is the maximum number of probe blocks 141 arranged along the y-axis of the probe area 131, and Z is the number of probe blocks 141 that may be formed on the probe card 101.

Accordingly, the probe card 101 having the probe area 131 with dimensions 16 cm×16 cm may not be suitable for testing an 8-inch wafer 211 on which the 175 semiconductor chips 221 are formed in one operation.

Therefore, as illustrated in FIG. 3, it may be necessary to perform the EDS test at least three times (311, 321, 331) such that all of the 175 semiconductor chips 221 may be tested. For example, if the time required to perform the EDS test on the semiconductor chip 221 is assumed to be one hour, and, secondly, it takes one hour to perform one EDS test on the wafer 211, then the time required to test the wafer 211 may be at least three hours because the EDS test must be performed three times.

As described above, when the EDS test is performed on the semiconductor chips 221 formed on the wafer 211 using a conventional probe card 101 for testing multi-chips, the EDS test may be performed several times, thus possibly resulting in a longer testing time. In particular, when the semiconductor chip 221 has a large size, the time required to perform the EDS test on all of the semiconductor chips 221 formed on the wafer 211 may be larger.

### SUMMARY OF EXAMPLE EMBODIMENTS OF THE INVENTION

Example embodiments of the present invention provide a probe card for performing an electrical die sort (EDS) test on a plurality of semiconductor chips on a wafer in a reduced amount of time.

According to an example embodiment of the present invention, there is provided a probe card for testing a plurality of semiconductor chips, formed on a wafer. The probe card may include a substrate; a plurality of probe blocks, arranged on the substrate, which may form a pattern corresponding to the pattern formed by the semiconductor chips on the wafer; and a plurality of probe needles, which may be mounted on the probe blocks, arranged in a pattern corresponding to a plurality of pads, which may be mounted on the plurality of semiconductor chips.

A number of the plurality of probe blocks may be less than a number of the semiconductor chips formed on the wafer. The substrate may include a printed circuit board including a circuit which connects the probe needles to an external system; a plurality of contact pads which electrically connects to an external system; and a fixing plate which connects the probe area to the substrate.

According to another example embodiment of the present invention, there may be provided a probe card for testing a plurality of semiconductor chips formed on a wafer, the probe card may include a substrate; a plurality of probe blocks arranged on the substrate; and a plurality of probe needles may be mounted on the probe blocks and arranged in a pattern corresponding to a plurality of pads (not shown), which may be mounted on the plurality of semiconductor chips. Further, the plurality of probe blocks may be arranged in a structure (e.g., hexagon, octagon, decagon, etc.) such that the plurality of probe blocks along every other side of the structure are arranged in an approximately linear configuration (e.g., a straight or substantially straight line) and the plurality of probe blocks along the other sides of the structure may form a linear or non-linear pattern (e.g., stepped or scalloped), and a first pair of patterned, opposite-facing sides may have the same shape as two corresponding patterned sides of the plurality of semiconductor chips. It should be appreciated that the structure, linear and non-linear configurations are not limited to the examples provided.

A number of the plurality of probe blocks may be less than a number of the plurality of semiconductor chips formed on the wafer. A second pair of patterned, opposite-facing sides, may have a similar pattern to two corresponding sides of the plurality of semiconductor chips.

According to yet another example embodiment of the present invention, there may be provided a probe card for testing a plurality of semiconductor chips formed on a wafer, the probe card may include a substrate; a plurality of probe blocks arranged on the substrate; and a plurality of probe needles that may be mounted on the plurality of probe blocks and arranged in a pattern corresponding to a plurality of pads mounted on the plurality of semiconductor chips. Further, the plurality of probe blocks may be arranged in a structure such that the probe blocks along every other side of the structure may be arranged in a linear or approximately linear configuration and the plurality of probe blocks along the other sides of the structure may form a linear or non-linear pattern, a first pair of the non-linear patterned, opposite-facing sides may have a corresponding pattern as two corresponding sides of the plurality of semiconductor chips, and a pair of the patterned, opposite-facing sides may be shorter than two corresponding sides of the pattern formed by plurality of semiconductor chips.

According to example embodiments of the present invention, when the EDS testing time for the wafer is decreased, productivity may be increased.

### BRIEF DESCRIPTION OF THE DRAWINGS

Example embodiments of the present invention may become more apparent by describing in detail the example embodiments thereof with reference to the attached drawings in which:

FIG. 1 is a plan view of a conventional probe card that may be used to test multi-chips;

FIG. 2 is a plan view of a wafer with semiconductor chips thereon;

FIG. 3 illustrates various arrangements of the plurality of semiconductor chips that may be connected to the plurality of probe needles of the probe card illustrated in FIG. 1 when the wafer illustrated in FIG. 2 is tested using the conventional probe card illustrated in FIG. 1;

FIG. 4 is a plan view of a probe card for testing a plurality of semiconductor chips according to an example embodiment of the present invention;

FIG. 5 is a sectional view of the probe card illustrated in FIG. 4;

FIG. 6 illustrates various arrangements for the plurality of semiconductor chips that may be connected to the plurality of probe needles of the probe card illustrated in FIG. 4 when the wafer of FIG. 2 is tested using the probe card illustrated in FIG. 4; and

FIG. 7 is a schematic diagram of an apparatus that may be used to perform an EDS test on the wafer illustrated in FIG. 2 using the probe card illustrated in FIG. 1.

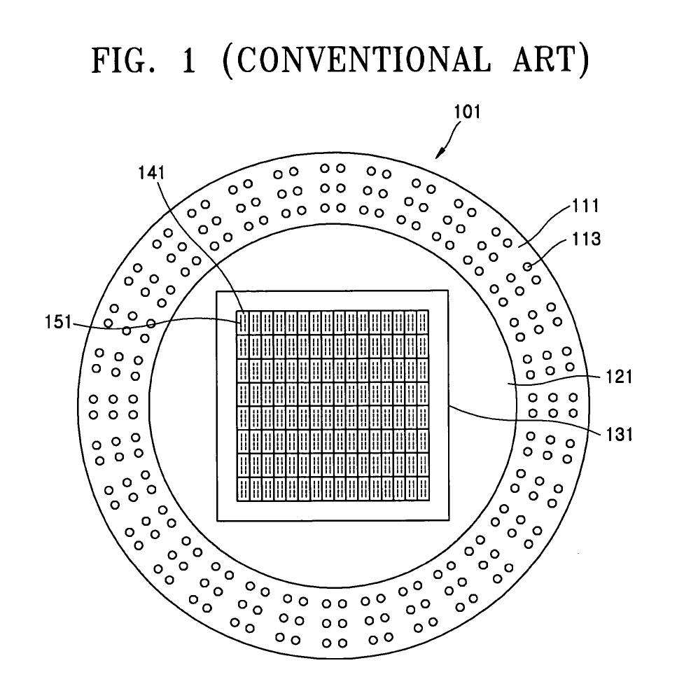

### DETAILED DESCRIPTION OF EXAMPLE EMBODIMENTS OF THE INVENTION

Example embodiments of the present invention will now be described more fully with reference to the accompanying drawings. Like reference numerals denote like elements in the drawings, and thus their description will not be repeated.

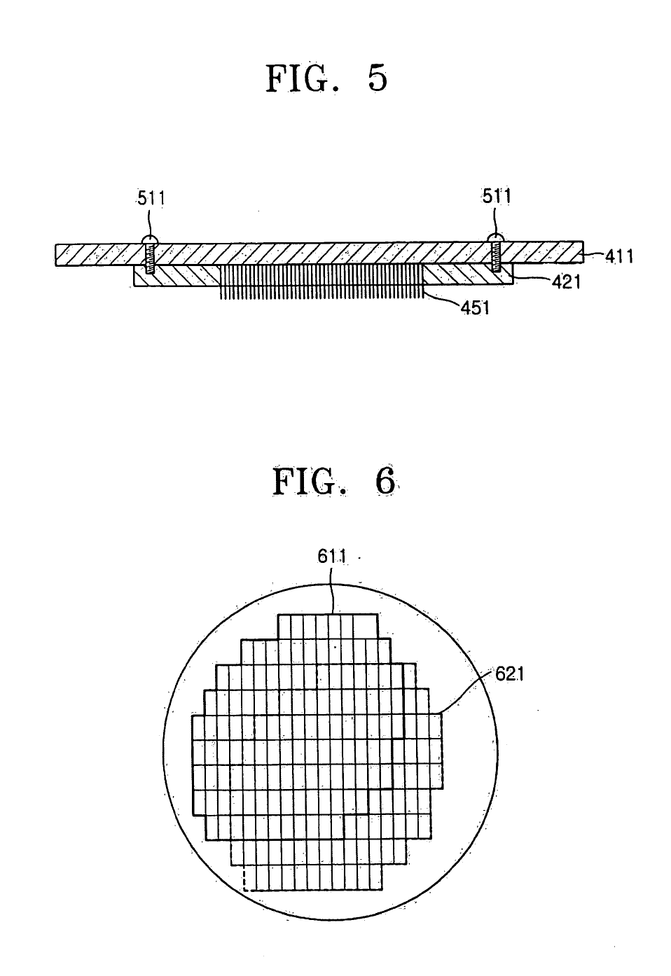

FIG. 4 is a plan view of a probe card 401 which may be used for testing a plurality of semiconductor chips according to an example embodiment of the present invention. FIG. 5 is a sectional view of the probe card 401. Referring to FIGS. 4 and 5, the probe card 401 may include a substrate 411, plurality of probe blocks 441, and plurality of probe needles 451.

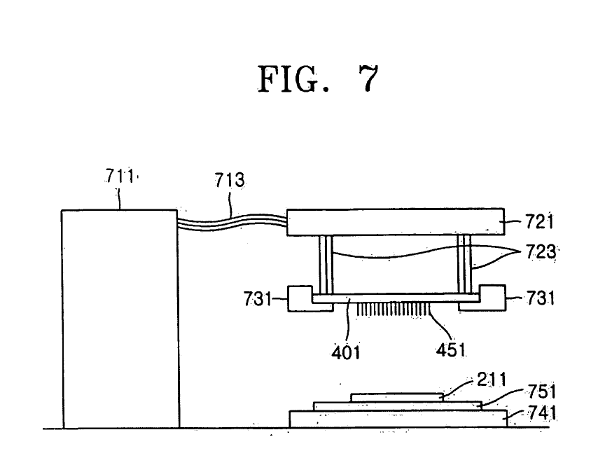

The substrate 411 may be coupled to a fixing plate 421 by connecting members 511. The fixing plate 421 may fix the substrate 411 such that the substrate 411 may not bend. Contact pads 413 and probe needles 451 may be mounted on the substrate 411. The substrate 411 may include a printed circuit board, including a circuit, which may electrically connect the contact pads 413 to probe needles 451. The contact pads 413 may connect to an external system (illustrated as test equipment 711 in FIG. 7). The circuit may be formed on any surface of the substrate 411. Alternatively, a plurality of substrates 411 may be formed (e.g., by placing them adjacent to one another). In other words, the structure of the substrate 411 may not be limited to the single substrate shown in FIG. 4 and various changes in form and details may be made by those skilled in the art.

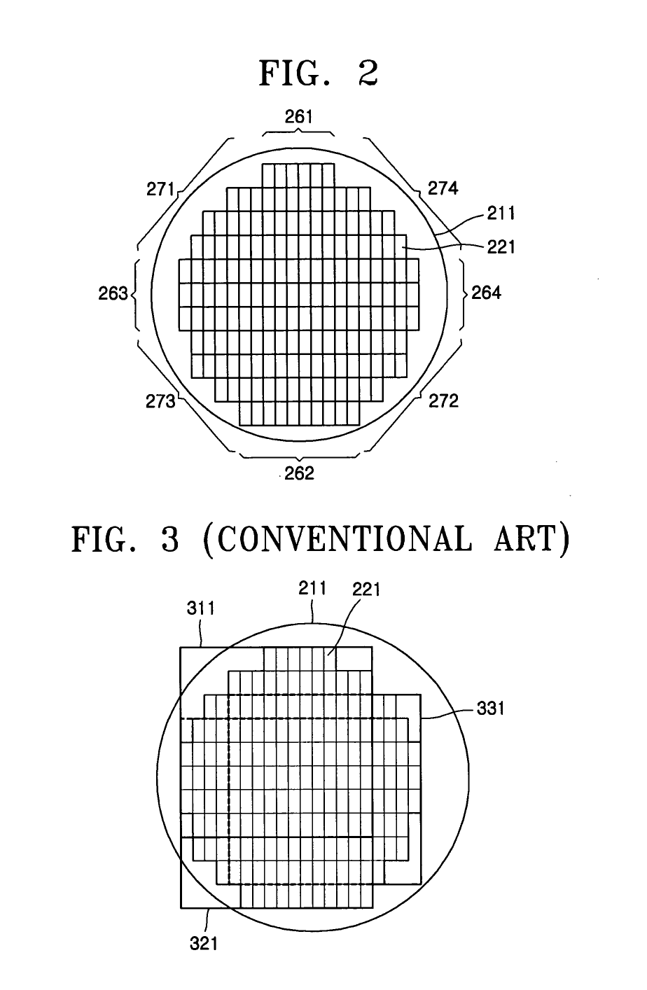

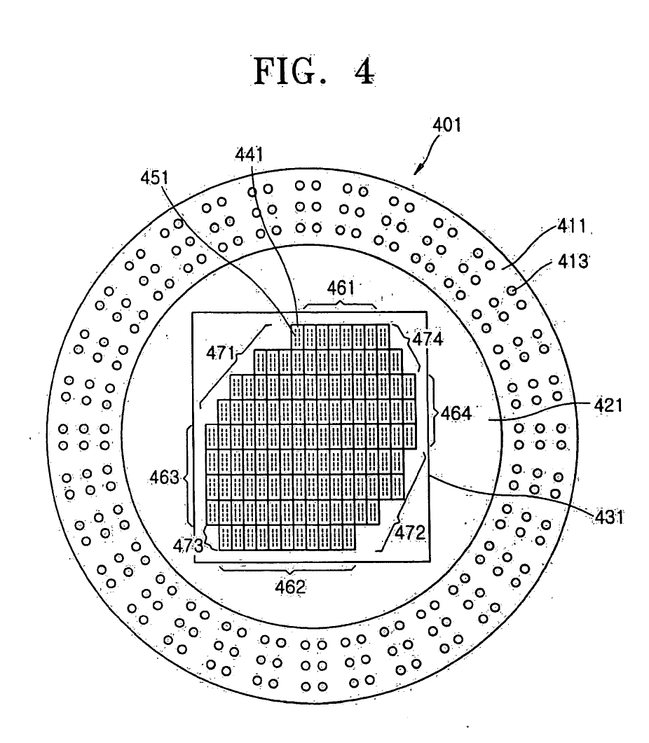

Referring to FIG. 4, in another example embodiment of the present invention, non-adjacent sides 461 through 464 of the probe area 431 may have an approximately linear configuration, and the other non-adjacent sides 471 through 474 form a non-linear and/or linear pattern. The approximately linear configuration may be a straight or approximately straight line. Thus, the non-adjacent sides 461 through 464 of the probe area 431 may be straight or substantially straight lines. And, the non-adjacent sides 471 through 474 may be incrementally stepped-up to form stepped sides, or stepped-up and rounded to form scalloped, stepped sides. Or, non-adjacent sides 471 through 474 may be straight or substantially straight lines. Further, the non-adjacent sides may correspond to every other side of the probe area 431. The pattern formed by the plurality of probe blocks 441, or plurality of probe needles 451, may correspond to the pattern formed by the plurality of semiconductor chips 221 formed on the wafer 211 illustrated in FIG. 2. Further, the plurality of probe blocks 441, or probe area 431, may be arranged in a hexagon, octagon, or decagon, etc. In other words, the shape of the probe area is not limited to the examples provided.

According to another example embodiment of the present invention, the sides 461 through 464 of the probe area 431 may have an approximately linear configuration; and the pattern formed along sides 473 and 474 of the probe area 431 may correspond to the pattern formed along sides 273 and 274 of the semiconductor chips 221, respectively; and the pattern formed along sides 471 and 472 of the probe area 431 may be correspond to the pattern formed along sides 271 and 272 of the semiconductor chips 221, respectively.

According to still another example embodiment of the present invention, the sides 461 through 464 of the probe area 431 may have an approximately linear configuration; and the pattern formed along sides 471, 472, 473, 474 of the probe area 431 and the pattern formed along sides 271, 272, 273, 274 of the semiconductor chips 221 may respectively have corresponding and/or identical forms. However, the sides 471 and 472 of the probe area 431 may be shorter than the corresponding sides 271 and 272 of the semiconductor chips 221; and the sides 473 and 474 of the probe area 431 may be shorter than the corresponding sides 273 and 274 of the semiconductor chips 221.

These various structures of the probe area 431 may result in the same effect.

A plurality of probe needles 451 may be mounted on the probe area 431. The plurality of probe needles 451 installed in the probe area 431 may form an arrangement corresponding to the plurality of pads (not shown) mounted on the semiconductor chips 221. In other words, the arrangement of the plurality of probe needles 451, which may be mounted in the probe area 431 of the probe card, may be identical to the arrangement of the plurality of pads of one semiconductor chip 221. For example, when the plurality of pads mounted on each of the plurality of semiconductor chips 221 are arranged in two lines, the plurality of probe needles 451 mounted in the probe area 431 may also be arranged in two lines. In this case, the number of the plurality of probe needles 451 mounted on the probe area 431 may be approximately equal to or greater than the number of the pads mounted on each of the plurality of semiconductor chips 221.

FIG. 6 illustrates various arrangements of the plurality of semiconductor chips 221 that may be connected to the plurality of probe needles 451 of the probe card 401 when the wafer of FIG. 2 is tested using the probe card 401. Performance of an electrical die sort (EDS) test on the semiconductor chips 221 using the probe card 401 will now be described with reference to FIGS. 2, 4 and 6.

When the wafer 211 has a diameter of 8-inches and the semiconductor chip 221 has a size of X(16 cm)×Y(16 cm), 175 semiconductor chips 221 may be formed on the wafer 211. Accordingly, when the probe area 431 of the probe card 401 has a size of X(16 cm)×Y(16 cm), 125 probe blocks 441 may be formed in the probe area 431. A maximum of 17 probe blocks 441 may be arranged along an x-axis of the probe area 431, and a maximum of 9 probe blocks 441 may be arranged along a y-axis of the probe area 431. When the width and length of the semiconductor chips 221 are 0.91 cm and 1.604 cm, respectively, this arrangement may be formed within the probe area 431 of the probe block 441. In other words, all of the probe blocks 441 may be disposed in the 16 cm×16 cm probe area 431, which may be confirmed by the following example calculations using Equation (1):
Z=X×Y=17×0.91 cm=15.47 cm
Z=X×Y=9×1.604 cm=14.436 cm

Because the plurality of probe blocks 441, which may be formed in the probe area 431, may also be arranged in an octagon structure, only 125 probe blocks 441 may be disposed in the probe area 431. In other words, the number (e.g., 125) of probe blocks 441 disposed in the probe area 431 of the probe card 401 may be equal to or less than the number (e.g., 128) of probe blocks 141 disposed in the probe area 131 of the conventional probe card 101 and the number of semiconductor chips 221 on the wafer 211. Accordingly, when the probe card 401 is used, the EDS test may be performed on only some of the plurality of semiconductor chips 221.

However, because the arrangement of the plurality of probe blocks 441 of the probe card 401 according to an example embodiment of the present invention may be similar to the arrangement of the semiconductor chips 221 formed on the wafer 211, the EDS test may need to be performed on the wafer 211 only two times (611 and 621) using the method illustrated in FIG. 6. For example, if the time required to perform the EDS test on each of the plurality of semiconductor chips 221 is assumed to be one hour and the time required to perform one EDS test on the wafer 211 is also one hour, then the time required to perform EDS test for the wafer 211 may take a minimum of two hours because the EDS test must be performed two times.

As described above, when the EDS test is performed on the wafer 211 using the conventional probe card 101, it may take a minimum of three hours. However, when the probe card 401 according to an example embodiment of the present invention is used, it may take a minimum of two hours. In other words, according to an example embodiment of the present invention, the time required to perform the EDS test on the wafer 211 may be decreased by 33.3%, thus increasing productivity by 33.3%.

Examples of conventional probe cards may include PA85 (8.5 cm×8.5 cm), PA120 (12 cm×12 cm), PA160 (16 cm×16 cm), PA200 (20 cm×20 cm) and the like.

A method of testing the wafer 211 of FIG. 2 using the probe card 401 illustrated in FIG. 4 will now be described with reference to FIG. 7.

Referring to FIG. 7, in order to perform the EDS test, the wafer 211 may be placed on a chuck 751 disposed on a probe station 741. Pogo connectors 723 of a test head 721, which may connect to an external system 711 (illustrated as test equipment) through a cable 713, may connect with the probe card 401 held by card holders 731. Then, the probe card 401 may be moved downward such that the plurality of probe needles 451 contacts the plurality of pads (not shown) of the semiconductor chips 221, formed on the wafer 211. In this state, the test equipment 711 may send electric signals to the semiconductor chips 221 via the plurality of probe needles 451. When malfunctioning semiconductor chips are found, the malfunctioning semiconductor chips may be highlighted with a signal. As a result, packaging of the malfunctioning semiconductor chips may be reduced or prevented.

As described above, the pattern formed by the plurality of probe blocks of the probe card according to the example embodiments of the present invention may be similar to the patterned formed by the plurality of semiconductor chips formed on a wafer. Therefore, the time required to perform EDS test on the wafer may be decreased, thus increasing the yield of the wafers.

While the present invention has been particularly shown and described with reference to example embodiments thereof, it will be understood by those of ordinary skill in the art that various changes in form and details may be made therein without departing from the spirit and scope of the example embodiments as defined by the following claims.

What is claimed is:

1. A probe card for testing a plurality of semiconductor chips formed on a wafer, the probe card comprising:
a substrate;
a plurality of probe blocks arranged on the substrate; and
a plurality of probe needles mounted on the plurality of probe blocks and arranged in a corresponding shape to that of a plurality of pads mounted on the plurality of semiconductor chips.

2. The probe card according to claim 1, wherein a number of the plurality of probe blocks is less than or equal to a number of the plurality of semiconductor chips formed on the wafer.

3. The probe card according to claim 1, wherein a number of the plurality of probe needles in the probe area is greater than or equal to a number of the plurality of pads formed on the plurality of semiconductor chips.

4. The probe card according to claim 1, wherein the substrate includes:
a fixing plate which connects the probe area to the substrate;
a printed circuit board which electrically connects the plurality of probe needles to a plurality of contact pads; and
further wherein the plurality of contact pads electrically connects to an external system.

5. The probe card according to claim 4, wherein a number of the plurality of probe blocks is less than or equal to a number of the plurality of semiconductor chips formed on the wafer.

6. The probe card according to claim 1, wherein:
the plurality of probe blocks along non-adjacent sides is arranged in an approximately linear configuration; and
the plurality of probe blocks along the other non-adjacent sides forms a non-linear pattern.

7. The probe card according to claim 6, wherein:
at least one pair of the patterned, opposite-facing sides of the probe area have a similar, or identical, pattern to a pair of corresponding sides of the plurality of semiconductor chips; and
at least one pair of the patterned, opposite-facing sides of the probe area have a similar, but not identical, pattern as a pair of corresponding sides of the plurality of semiconductor chips.

8. The probe card according to claim 6, wherein at least two pairs of patterned, opposite-facing sides of the probe area have a similar pattern as two corresponding identical sides of the plurality of semiconductor chips.

9. The probe card according to claim 6, wherein the approximately linear configuration is a straight line.

10. The probe card according to claim 6, wherein the plurality of probe blocks is arranged in an octagon.

11. The probe card according to claim 6, wherein the plurality of probe blocks along non-adjacent sides corresponds to every other side of the probe area.

12. The probe card according to claim 6, wherein the patterned sides are stepped sides.

13. The probe card according to claim 6, wherein a pair of the patterned, opposite-facing sides of the probe area is shorter than two corresponding sides of the pattern formed by the plurality of semiconductor chips.

14. A probe card for testing a plurality of semiconductor chips formed on a wafer, the probe card comprising:
a substrate;
a plurality of probe blocks arranged on the substrate; and
a plurality of probe needles mounted on the plurality of probe blocks and arranged in a stepped configuration corresponding to a plurality of pads mounted on the plurality of semiconductor chips.

15. The probe card according to claim 14, wherein a number of the plurality of probe blocks is less than or equal to a number of the plurality of semiconductor chips formed on the wafer.

16. The probe card according to claim 14, wherein a number of the plurality of probe needles in the probe area is greater than or equal to a number of the plurality of pads formed on the plurality of semiconductor chips.

17. The probe card according to claim 14, wherein the substrate includes:
a fixing plate which connects the probe area to the substrate;
a printed circuit board which electrically connects the plurality of probe needles to a plurality of contact pads; and
further wherein the plurality of contact pads electrically connects to an external system.

18. The probe card according to claim 14, wherein the plurality of probe blocks form a stepped pattern corresponding to the stepped pattern formed by the plurality of semiconductor chips formed on the wafer.

19. The probe card according to the method of claim 14, wherein:
the plurality of probe blocks along non-adjacent sides are arranged in an approximately linear configuration; and
the plurality of probe blocks along the other non-adjacent other sides form a stepped pattern.

20. The probe card according to claim 19, wherein:
at least one pair of the stepped, opposite-facing sides of the probe area have a similar, or identical, pattern as a pair of corresponding stepped sides of the plurality of semiconductor chips; and
at least one pair of the stepped, opposite-facing sides of the probe area have a similar, but not identical, pattern as a pair of corresponding sides of the plurality of semiconductor chips.

21. The probe card of claim 19, wherein at least two pairs of patterned, opposite-facing sides of the probe area have a similar, or identical, pattern as two corresponding sides of the plurality of semiconductor chips.

22. The probe card according to claim 19, wherein the approximately linear configuration is a straight line.

23. The probe card according to claim 19, wherein the plurality of probe blocks is arranged in an octagon.

24. The probe card according to claim 19, wherein the plurality of probe blocks along non-adjacent sides corresponds to every other side of the probe area.

25. The probe card according to claim 16, wherein a pair of the patterned, opposite-facing sides of the probe area are shorter than two corresponding sides of the pattern formed by the plurality of semiconductor chips.

26. A method for testing a plurality of semiconductor chips formed on a wafer using the probe card as claimed in claim 1, comprising:
installing a plurality of probe needles in the probe blocks;
arranging the probe needles in a pattern corresponding to the pads formed in the semiconductor chips; and
contacting a plurality of probe needles of the probe card to a plurality of pads of the semiconductor chip via a downward movement.

27. A method for testing a plurality of semiconductor chips formed on a wafer using a probe card including a plurality of probe blocks arranged in a corresponding pattern to that of a plurality of pads formed on the semiconductor chips, comprising:
placing a wafer on a chuck disposed on a probe station;
connecting a pogo connector of a test head with a probe card held by a card holder;
wherein the pogo connectors may connect to an external source through a cable;
contacting a plurality of probe needles of the probe card to a plurality of pads of the semiconductor chip via a downward movement;
sending an electric signal to the semiconductor chips via the external system, highlighting a malfunction semiconductor chip via a signal; and
preventing the packaging of the malfunctioning semiconductor chip.
